(19) United States
(12) Patent Application Publication
(10) Pub. No.: US 2021/0302523 A1
(43) Pub. Date: Sep. 30, 2021

(54) MAGNETIC RESONANCE TOMOGRAPHY UNIT AND SYSTEM AND METHOD FOR PREVENTING DISTURBANCES

(71) Applicant: Siemens Healthcare GmbH, Erlangen (DE)

(72) Inventors: David Grodzki, Erlangen (DE); Rainer Schneider, Erlangen (DE)

(21) Appl. No.: 17/199,682

(22) Filed: Mar. 12, 2021

(30) Foreign Application Priority Data
Mar. 31, 2020 (DE) 102020204167.9

(51) Int. Cl. G01R 33/54; G01R 33/36

(52) U.S. Cl. CPC G01R 33/543; G01R 33/3621

(57) ABSTRACT

The disclosure relates to a magnetic resonance tomography unit with a control unit for controlling an image acquisition. The control unit has an interface for a signal-carrying connection to a disturbance source. The control unit is configured to synchronize an image acquisition by an information exchange with the disturbance source.

The present patent document claims the benefit of German Patent Application No. 10 2020 204 167.9, filed Mar. 31, 2020, which is hereby incorporated by reference in its entirety.

### TECHNICAL FIELD

The disclosure relates to a magnetic resonance tomography unit and a disturbance source, as well as a method for operating the magnetic resonance tomography unit with the disturbance source, which reduces the disturbances by the disturbance source.

### BACKGROUND

Magnetic resonance tomography units are imaging apparatuses which, for imaging an examination object, align nuclear spins of the examination object with a strong external magnetic field and by an alternating magnetic field, excite them to precession about this alignment. The precession and/or the return of the spin from this excited state into a state with lower energy itself generates an alternating magnetic field as a response, also designated a magnetic resonance signal, which is received via antennae.

With the help of magnetic gradient fields, a position encoding is impressed upon the signals, which subsequently enables an allocation of the received signal to a volume element. The received signal is then evaluated, and a three-dimensional imaging representation of the examination object is provided. The representation created gives a spatial density distribution of the spin.

The attenuation between the excitation pulse and the magnetic resonance signal thereafter emitted by the patient or a sample is greater than 100 dB. The detection of the magnetic resonance signals is accordingly sensitive and easily disturbed. While external signal sources in the environment of the magnetic resonance tomography unit may be suppressed by suitable screened cabins, there are also disturbance sources which are arranged within the screened cabin. These may be apparatuses for communication with or entertainment of the patient, but also devices for medical supply to, or monitoring of, the patient. It may not be possible or economical in certain cases to interference suppress or screen these apparatuses sufficiently in accordance with the requirements of the magnetic resonance tomography unit.

### SUMMARY AND DESCRIPTION

It is an object of the present disclosure to provide a magnetic resonance tomography unit and a method for operation which reduces such disturbances.

The object is achieved by a magnetic resonance tomography unit and a method as disclosed herein. The scope of the present disclosure is defined solely by the appended claims and is not affected to any degree by the statements within this summary. The present embodiments may obviate one or more of the drawbacks or limitations in the related art.

The magnetic resonance tomography unit has a control unit for controlling an image acquisition. This controls, for example, the cooperation of the units required for the image acquisition, for example, high frequency transmitters for exciting the nuclear spin, gradient generation and magnetic resonance signal receivers and the acquisition of the received signals.

Furthermore, the control unit has an interface in order to provide a signal connection to a disturbance source. Depending upon the embodiment described below, the interface may be configured to receive signals from the disturbance source, to output signals to the disturbance source, or to provide a signal-carrying connection in both directions. The interface may be electrical, but may also be via wireless signals, optical, or mechanical, (e.g., using pneumatics or hydraulics).

The control unit of the magnetic resonance tomography unit is configured to adjust an image acquisition by an information exchange with the disturbance source. Different embodiments for an adjustment are disclosed herein. In the context of the disclosure, this is to be understood as meaning that the magnetic resonance tomography unit, the disturbance source, or both change at least one operating parameter on the basis of the information exchange, so that disturbances in an image reconstructed from the acquired magnetic resonance signals are reduced.

Advantageously, it is possible by adjustment between the disturbance source and the magnetic resonance tomography unit, even without complex screening measures, to improve the image quality.

The method shares the advantages of the magnetic resonance tomography unit disclosed herein.

In one possible embodiment of the magnetic resonance tomography unit, the control unit is configured to receive a signal via the interface with an item of information from the disturbance source regarding an activity. In other words, the control unit is able to receive a signal which emerges from the disturbance source via the interface, so that the control unit may evaluate the signal and/or adjust further acts or parameters of an image acquisition dependent thereon. The signal may be analog, for example, a status signal or a level, or may be a digital signal with an encoded item of information, for example, via a network or a bus protocol. The signal may be transferred electrically, wirelessly via high frequency electrical and/or magnetic fields or optically. The signal has an item of information regarding an activity of the disturbance source, in particular an activity or an operational state of the disturbance source which has an influence on an electromagnetic emission of the disturbance source. Thus, for example, the control unit may determine, on the basis of the item of information, whether an emission in a particular frequency range exceeds a particular level. It is conceivable that such an item of information is encoded directly in the signal or that an operational state is encoded, and the control unit extracts corresponding data regarding disturbances for this operational state from a memory store.

Advantageously, the control unit may draw conclusions via knowledge about an activity or an operational state of the disturbance source regarding possible disturbances and take corresponding measures for their reduction.

In one conceivable embodiment of the magnetic resonance tomography unit, the control unit is configured to control an activity of the disturbance source by a signal with a command via the interface to the disturbance source. The command may be an analog or digitally encoded signal which is transferred, for example, via an electrical line by high-frequency electrical and/or magnetic alternating fields or optically. The command may be a switch-on or a switch-off, including through interruption of the supply voltage, or an instruction for interrupting an activity or for changing an operational parameter, for example, a frequency or a power level.

Advantageously, commands via the interface enable the control unit to influence the disturbance source such that disturbances, in particular, in sensitive time portions of a sequence, such as the reception of MR signals, are reduced by changing the activity or are displaced into a non-critical frequency range.

In a possible embodiment of the magnetic resonance tomography unit, the signal has an item of information regarding a time point and/or frequency of the activity. In one case, this may be a pre-determined signal level which, dependent on whether it is an item of information about the activity or a command, either shows that the disturbance source is currently carrying out an activity with disturbance emission or the magnetic resonance tomography unit is currently undertaking a disturbance-sensitive signal acquisition. It is also conceivable that more complex messages are exchanged which enable, by a specification regarding the pre-determined time point of the execution and/or the frequency concerned of the activity of the respective other side, the disturbance sensitive or disturbing activities to be synchronized accordingly and thereby to reduce a disturbance of the image acquisition in an advantageous manner.

In a conceivable embodiment of the magnetic resonance tomography unit, the control unit is configured to change a frequency of an image acquisition process dependent upon the received information. For example, it is conceivable that by suitable slice selection and gradients, the frequency of a magnetic resonance signal is shifted. In suitable magnetic resonance systems with field magnets that may be influenced by the control unit, the value of the static magnetic field B0, and therewith the Larmor frequency, may be changed.

In an advantageous manner, by an item of information regarding the frequencies affected, an image acquisition process may be adapted so that the effect of an activity of the disturbance source on the image acquisition is reduced.

In a possible embodiment of the magnetic resonance tomography unit, the magnetic resonance tomography unit has a receiver as the interface. This may be a separate receiver or a receiver of the magnetic resonance tomography unit, which is provided for receiving magnetic resonance signals for image acquisition. The control unit is in signal connection with the receiver in order to obtain information regarding received high frequency signals. Thereby, the control unit is configured to acquire, by the receiver, an activity of the disturbance source and to carry out the image acquisition dependent upon the acquired activity. For example, a frequency of the disturbance source may be concluded from the received signal and the image acquisition may be modified as described above. It is also conceivable, in the case of a narrow-band disturbance, to adjust filters in the receiving path or to suppress artifacts in a targeted manner in the k-space during the image reconstruction. Where a separate receiver is used, this may also take place during the acquisition of the MR signals, whereas on use of a receiver for magnetic resonance signals, this is possible only outside the image acquisition.

Advantageously, by a receiver for receiving the disturbance signals, an activity of the disturbance source may also be concluded and thereby, the image acquisition may be adapted such that disturbances are reduced.

The method for operating the magnetic resonance tomography unit has the act of adjusting the control unit to the disturbance source by a signal via the interface. Adjusting is understood here to be the exchange of information via the interface and a change of an activity on at least one side dependent upon this information, leading to a reduction in disturbances in the image acquisition by the disturbance source. This may be a change of a parameter of the image acquisition on the part of the magnetic resonance tomography unit or, on the part of the disturbance source, an altered operational state with less or changed emissions. In a further act, the control unit then carries out an image acquisition with the magnetic resonance tomography unit, which due to the adjustment has reduced disturbances.

In a conceivable embodiment of the method, the signal is a command from the control unit via the interface to the disturbance source which is configured to change an emission property of the disturbance source. As stated above, in the simplest case, this may be a switching off or an instruction to interrupt or displace an activity or a change of an operational parameter, such as for example, a frequency or power level.

Through a change in the emission properties of the disturbance source, a disturbance in the image acquisition may advantageously be reduced.

In a possible embodiment of the method, the control unit receives the signal from the disturbance source via the interface. The signal has an item of information regarding an operational state of the disturbance source. For example, the signal may indicate that the disturbance source is active. More complex information such as the frequency of a disturbance signal or the amplitude or an intended execution time point may also be included. The control unit carries out the image acquisition dependent upon the information. For example, a sequence may be altered such that a reception of a magnetic resonance signal does not coincide with a disturbing activity of the disturbance source. Also conceivable, as described above, for example, are adaptation of the frequency or filter measures in the receiver or in the image reconstruction.

Advantageously, an adaptation of the magnetic resonance sequence to an activity of the disturbance source permits a reduction of the artifacts caused by the disturbance source in the magnetic resonance images acquired.

In a conceivable embodiment of the method, the method further includes the act of synchronizing the control unit with the disturbance source. This is to be understood as meaning that the control unit is informed by the signal about a current operational state of the disturbance source. This may take place by the control unit sending as the signal a command via the interface to the disturbance source, wherein the disturbance source is placed in or maintains a pre-determined state. Alternatively, it is also possible that the disturbance source transmits a signal with an item of information regarding a current operational state or activity to the control unit.

In a further act, the control unit acquires by the magnetic resonance tomography unit, a disturbance emitted by the disturbance source in the current operational state, for example, by the receivers for magnetic resonance signals or a dedicated receiver for high frequency signals. The control unit is thus able to acquire and store emissions of the disturbance source that are associated with an operational state or activity of the disturbance source. In a later act, the control unit is then able to undertake changes of parameters or other disturbance suppression measures suited to an operational state or an activity without directly acquiring them with high frequency techniques, which is then made more difficult, for example, by other signals of the magnetic resonance scan. Advantageously, the disturbance suppression may thus be improved.

If the disturbance source is a permanent component of the magnetic resonance tomography unit, for example, a tablet for operation or a display or a camera for communication with the patient, these acts may also take place in the production process or during installation of the magnetic resonance tomography unit by the service personnel.

### BRIEF DESCRIPTION OF THE DRAWINGS

The above-described properties, features, and advantages of this disclosure and the manner in which they are achieved are made more clearly and distinctly intelligible with the following description of the exemplary embodiments which are described in greater detail within to the drawings. In the drawings:

FIG. 1 is a schematic representation of a magnetic resonance tomography unit according to an embodiment.

FIG. 2 is a schematic representation of units of the magnetic resonance tomography unit according to an embodiment.

FIG. 3 is a schematic flow diagram of a method according to an embodiment.

### DETAILED DESCRIPTION

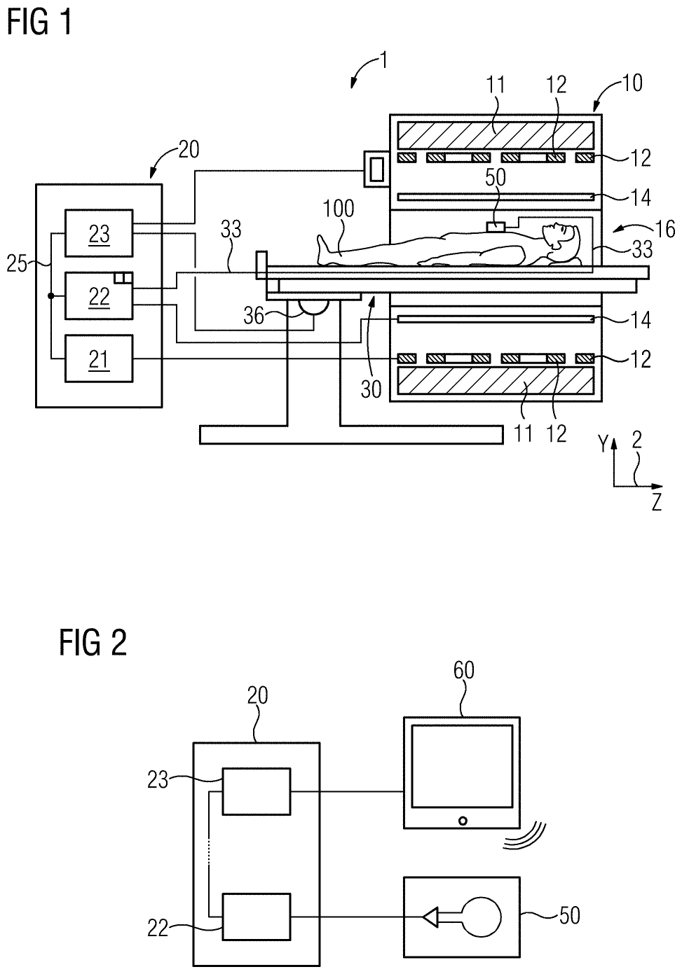

FIG. 1 depicts a schematic representation of an embodiment of a magnetic resonance tomography unit 1 with a disturbance source 60.

The magnet unit 10 has a field magnet 11 which generates a static magnetic field B0 for aligning the nuclear spins of samples or of the patient 100 in a scanning region. The scanning region is characterized by an extremely homogenous static magnetic field B0, wherein the homogeneity relates, in particular, to the magnetic field strength and/or the magnitude. The scanning region is almost spherical and is arranged in a patient tunnel 16 which extends in a longitudinal direction 2 through the magnet unit 10. A patient support 30 is movable in the patient tunnel 16 by the displacement unit 36. The field magnet 11 may be a superconducting magnet which may provide magnetic fields with a magnetic flux density of up to 3 T and in the newest devices even higher. For weaker field strengths, however, permanent magnets or electromagnets with normally-conducting coils may also be used.

The magnet unit 10 further includes gradient coils 12 which are configured, for spatial differentiation of the acquired imaging regions in the examination volume, to overlay variable magnetic fields onto the magnetic field B0 in three spatial directions. The gradient coils 12 may be coils made of normally-conducting wires which may generate mutually orthogonal fields in the examination volume.

The magnet unit 10 also has a body coil 14 which is configured to emit a high frequency signal fed via a signal line into the examination volume and to receive resonance signals emitted from the patient 100 and to pass them on via a signal line.

A control unit 20 supplies the magnet unit 10 with the different signals for the gradient coils 12 and the body coil 14 and evaluates the received signals.

Thus, the control unit 20 has a gradient controller 21 which is configured to supply the gradient coils 12 via feed lines with variable currents which provide the desired gradient fields in the examination volume in a temporally coordinated manner.

Furthermore, the control unit 20 has a high frequency unit 22 which is configured to generate a high frequency pulse with a pre-determined temporal sequence, amplitude, and spectral power distribution for excitation of a magnetic resonance of the nuclear spin in the patient 100. Thereby, pulse power levels in the region of kilowatts may be achieved. The excitation pulses may be emitted via the body coil 14 or via a local transmitting antenna into the patient 100.

A controller 23 communicates via a signal bus 25 with the gradient controller 21 and the high frequency unit 22.

The control unit 20 of the magnetic resonance tomography unit is provided with an interface 26 by which a communication with the disturbance source 60 may take place. Regarded as a disturbance source are all facilities in or about the magnetic resonance tomography unit 1 which disturb, by electromagnetic emissions, an image acquisition by the magnetic resonance tomography unit 1 and thereby may generate artifacts in the images. In particular, this may involve facilities that are not directly part of the magnetic resonance tomography unit 1, but rather are added for supportive functions and for this purpose may be procured from commercial sources. These may be input or output devices for operation and for image reproduction, medical monitoring devices for the patient, or auxiliary equipment for communication with the patient, (e.g., cameras, displays, or projectors).

Arranged on the patient 100 is a local coil 50, which is connected via a connection line 33 to the high frequency unit 22 and its receiver.

FIG. 2 again depicts units that are involved in the disclosure. Not shown are units from FIG. 1 which are required substantially unchanged for image acquisition. The same objects are provided with the same reference signs.

Examples of a disturbance source 60 are a display or tablet for operation. The disturbance source 60 is in signal-carrying connection with the controller 23 of the control unit 20 via a signal line as the interface. The interface may be an interface according to the standard USB, I2C, Ethernet, WLAN, CANbus, or other standardized interfaces and protocols. Also conceivable are proprietary interfaces through to simple electrical signals with just two levels. The signal-carrying connection may also take place herein via an optical waveguide or wirelessly. In certain examples, a wireless signal-carrying connection may thereby use frequencies that do not disturb the magnetic resonance scan. Disturbing emissions of the disturbance source are indicated as radio waves.

In one embodiment, the controller 23 uses the signal-carrying connection in order to transmit setting signals or commands to the disturbance source 60. The commands are configured to bring about a change in the emission of the disturbance source 60. It is conceivable, for example, that the controller 23 interrupts the energy feed or transmits a halt command. Also conceivable are more detailed settings with which a transmitting activity of the disturbance source, for example, the frequency is adjusted by a clock pulse change. In this way, the controller 23 may prevent emissions at a time point at which they would disturb the image acquisition.

In one embodiment, it is also conceivable that the disturbance source 60 transmits status messages via the signal-carrying connection to the control unit 20 or the controller 23, which has information regarding activities of the disturbance source with electromagnetic information, in particular, in the frequency range of the magnetic resonance signals. It is thereby also conceivable that these status messages are output before the activity and therein specify when the activity will take place. The controller 23 is then able to reduce the effects of the disturbance on the image acquisition in that the image acquisition is adapted. An altered time point by changes in the sequence, or a changed frequency is possible by adapting the static magnetic field B0 or the gradients for a slice. If the disturbing emission takes place during the acquisition of the magnetic resonance signals, the information may be used to activate filters at the frequency of the disturbance. Alternatively, the information is stored with the signals in order subsequently to filter or to suppress the disturbed signals during the image reconstruction in the k-space.

In one embodiment, it is also conceivable that the disturbing emission of the disturbance source 60 itself is the signal that the control unit 20 receives. It is conceivable, for example, that a receiver of the high frequency unit 22 receives the signal via the local coil 50, because disturbances in the frequency range of the magnetic resonance signals, in particular, are relevant to the quality of the image acquisition. Also possible is a separate receiver and/or antenna for acquiring the emission.

Also possible is combining a signal exchange in both directions, for example, in order to coordinate necessary activities on both sides and to prevent a time-out. In the context of the disclosure, a plurality of combinations are herein conceivable.

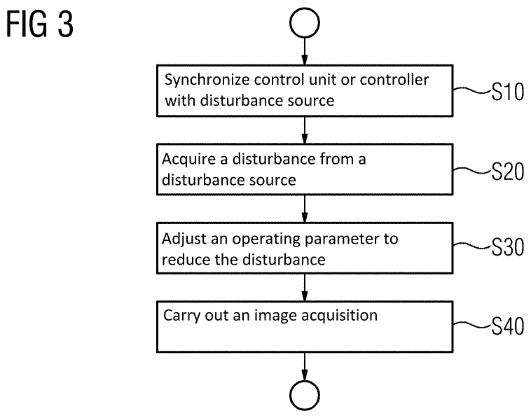

FIG. 3 depicts a schematic flow diagram of a method according to an embodiment.

In act S10, in a conceivable embodiment of the method, the control unit 20 or the controller 23 synchronizes with the disturbance source 60 by a signal via the interface. This may be a simple level on a line or a message via a standardized interface. What is provided in the context of the disclosure is that the other side is informed about the status of the first side in relation to the emissions of disturbances. This may be a command or a setting instruction of the controller 23 to the disturbance source 60 with which it is placed into a particular state with a pre-determined emission. However, it may also be a message or an item of information from the disturbance source 60 to the controller 23 regarding a current status or activity with a disturbance emission correlated therewith.

In act S20, the controller 23 or the control unit acquires a disturbance from the disturbance source 60 by the magnetic resonance tomography unit 1, for example, via the local coil 50 or a dedicated detector. On the basis of the preceding message or command, the acquired disturbance may be assigned to the respective state of the disturbance source. The acquisition may thereby include an analysis according to spectral distribution, amplitude, phase, or frequency of the disturbance signal. On the basis of this analysis, it is possible for the controller 23, if a status or state of the disturbance source 60 is known, later to take suitable measures and, for example, to adjust parameters of the image acquisition such as time point, frequency, filter coefficients, or image reconstruction algorithm in order to reduce a disturbance by the disturbance source 60.

It is thereby conceivable that the acts S10 and S20 take place in advance during the manufacturing of the magnetic resonance tomography unit 1 or during its installation and that the results are stored in the magnetic resonance tomography unit. Also conceivable is a database on a server or a cloud in which different disturbance profiles of different disturbance sources and their states are acquired, stored, and provided for a later access. The data regarding the disturbance source 60 may also be acquired and stored, without a magnetic resonance tomography unit, by a measuring apparatus.

In act S30 of the method, at least one operating parameter of the control unit 20 and/or the controller 23 and/or at least one operating parameter of the disturbance source 60 is adjusted by a signal via the interface in order to reduce a disturbance in the image acquisition. The at least one operating parameter may be adjusted based on the information exchange between the control unit 20/controller 23 and the disturbance source 60.

In a possible embodiment of the method, the signal is a command which is configured to change an emission property of the disturbance source. For example, the command may suppress a transmission, place the disturbance source in a holding state, or change a frequency of the transmission.

In another conceivable embodiment of the method, the control unit 20 receives the signal from the disturbance source 60 via the interface. The signal has an item of information regarding an operational state of the disturbance source. The information may directly describe a property of the emission of the disturbance source. It is, however, also conceivable that the information defines a pre-determined operational state, and the controller takes an item of information from the memory store or a database regarding an emission of the disturbance source in the operational state. The control unit 20 then carries out the image acquisition dependent upon the information. For example, the control unit 20 may delay a part of the sequence until the operational state of the disturbance source 60 changes. It is also conceivable that the control unit activates or adapts a filter or another disturbance suppression in order to reduce the effect of the disturbance source. It is also possible for the control unit to change, for example, the frequency of the magnetic resonance signals by changing the static magnetic field B0 or the gradient fields.

In act S40, the control unit 20 carries out an image acquisition with the magnetic resonance tomography unit 1 with the changed setting or the changed parameter, whereby the influence of the disturbance source is reduced.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

Although the disclosure has been illustrated and described in detail with the exemplary embodiments, the disclosure is not restricted by the examples disclosed and other variations may be derived therefrom by a person skilled in the art without departing from the protective scope of the disclosure.

1. A magnetic resonance tomography unit comprising:
a control unit for controlling an image acquisition; and
an interface for signal-carrying connection to a disturbance source,
wherein the control unit is configured to synchronize an image acquisition by an information exchange with the disturbance source.

2. The magnetic resonance tomography unit of claim 1, wherein the control unit is configured to receive a signal via the interface with an item of information from the disturbance source regarding an activity.

3. The magnetic resonance tomography unit of claim 2, wherein the item of information comprises a time point and/or frequency of the activity.

4. The magnetic resonance tomography unit of claim 3, wherein the control unit is configured to change a frequency of an image acquisition process dependent upon the item of information.

5. The magnetic resonance tomography unit of claim 1, wherein the control unit is configured to control an activity of the disturbance source by a signal with a command via the interface to the disturbance source.

6. The magnetic resonance tomography unit of claim 5, wherein the control unit is configured to change a frequency of an image acquisition process dependent upon an item of information.

7. The magnetic resonance tomography unit of claim 6, wherein the item of information comprises a time point and/or frequency of the activity.

8. The magnetic resonance tomography unit of claim 1, wherein the magnetic resonance tomography unit has a receiver as the interface, and
wherein the control unit is configured to acquire, by the receiver, an activity of the disturbance source and to carry out the image acquisition dependent upon the acquired activity.

9. A method for operating a magnetic resonance tomography unit with a control unit for controlling an image acquisition and an interface in signal-carrying connection with a disturbance source, the method comprising:
exchanging information between the control unit and the disturbance source via the interface;
adjusting at least one operating parameter of the control unit and/or the disturbance source based on the information exchange to reduce a disturbance in the image acquisition; and
carrying out the image acquisition by the control unit with the magnetic resonance tomography unit.

10. The method of claim 9, further comprising:
synchronizing the control unit with the disturbance source by a signal via the interface; and
acquiring the disturbance by the disturbance source by the magnetic resonance tomography unit.

11. The method of claim 9, wherein the signal is a command that changes an emission property of the disturbance source.

12. The method of claim 11, further comprising:
synchronizing the control unit with the disturbance source by a signal via the interface; and
acquiring the disturbance by the disturbance source by the magnetic resonance tomography unit.

13. The method of claim 9, wherein the control unit receives the signal from the disturbance source via the interface,
wherein the signal has an item of information regarding an operational state of the disturbance source, and
wherein the control unit carries out the image acquisition dependent upon the item of information.

14. The method of claim 13, further comprising:
synchronizing the control unit with the disturbance source by a signal via the interface; and
acquiring the disturbance by the disturbance source by the magnetic resonance tomography unit.
